(19) United States
(12) Patent Application Publication
(10) Pub. No.: US 2022/0336716 A1
(43) Pub. Date: Oct. 20, 2022

(54) DISPLAY DEVICE

(71) Applicant: Japan Display Inc., Tokyo (JP)

(72) Inventors: Jin HIROSAWA, Tokyo (JP); Masanobu IKEDA, Tokyo (JP); Yoshinori TANAKA, Tokyo (JP); Junko NAGASAWA, Tokyo (JP)

(73) Assignee: Japan Display Inc., Tokyo (JP)

(21) Appl. No.: 17/718,359

(22) Filed: Apr. 12, 2022

(30) Foreign Application Priority Data
Apr. 14, 2021 (JP) 2021-068360

(51) Int. Cl. H01L 33/58; H01L 33/56

(52) U.S. Cl. CPC H01L 33/58; H01L 33/56

(57) ABSTRACT

A display device includes a light emitting element and a first optical adjustment member located over the light emitting element and overlapping the light emitting element. An area of an upper surface of the first optical adjustment member is larger than an area of a lower surface of the first optical adjustment member. The display device further includes a second optical adjustment member in contact with a side surface of the first optical adjustment member. A refractive index of the second optical member is smaller than a refractive index of the first optical adjustment member.

### CROSS-REFERENCE TO RELATED APPLICATION

This application is based on and claims the benefit of priority from the prior Japanese Patent Application No. 2021-068360, filed on Apr. 14, 2021, the entire contents of which are incorporated herein by reference.

### BACKGROUND OF THE INVENTION

### Field

One embodiment of the present invention relates to a display device, particularly a display device including a light emitting diode (LED).

### Description of the Related Art

In recent years, a so-called micro LED display in which minute micro LEDs are arranged in pixels has been developed as a next-generation display. The micro LEDs are self-emitting elements similar to OLEDs, but unlike OLEDs, the micro LEDs are composed of inorganic compounds containing gallium (Ga) or indium (In). Therefore, it is easier to ensure a highly reliable micro LED display as compared with an OLED display. In addition, micro LEDs have high light emission efficiency and high brightness. Therefore, the micro LED display is expected to be the next generation display with high reliability, high brightness, and high contrast.

Generally, an LED emits light not only from the upper surface of the LED corresponding to the display surface of the display but also from the side surface of the LED. Therefore, a method of reflecting the light emitted from the side surface of the LED and changing the traveling direction of the light toward the upper surface direction of the LED is known (see, for example, International Publication No. 2021/033775).

### SUMMARY OF THE INVENTION

A display device according to one embodiment of the present invention includes a light emitting element and a first optical adjustment member located over the light emitting element and overlapping the light emitting element. An area of an upper surface of the first optical adjustment member is larger than an area of a lower surface of the first optical adjustment member.

A display device according to one embodiment of the present invention includes a light emitting element and a plurality of first optical adjustment members located over the light emitting element and overlapping the light emitting element. A total area of an upper surface of the plurality of first optical adjustment members is larger than a total area of a lower surface of the plurality of first optical adjustment members.

### BRIEF DESCRIPTION OF THE DRAWINGS

FIG. 1 is a schematic cross-sectional view of a display device according to an embodiment of the present invention;

FIG. 2 is a schematic plan view illustrating a positional relationship between a light emitting element and an optical adjustment member in a display device according to an embodiment of the present invention;

FIG. 3 is a schematic plan view illustrating a positional relationship between a light emitting element and an optical adjustment member in a display device according to an embodiment of the present invention;

FIG. 4 is a schematic cross-sectional view illustrating a method of manufacturing a display device according to an embodiment of the present invention;

FIG. 5 is a schematic cross-sectional view illustrating a traveling direction of light in a display device not provided with an optical adjustment member;

FIG. 6 is a schematic cross-sectional view illustrating a traveling direction of light in a display device according to an embodiment of the present invention;

FIG. 7 is a schematic cross-sectional view of a display device according to an embodiment of the present invention;

FIG. 8 is a schematic cross-sectional view of a display device according to an embodiment of the present invention; and

FIG. 9 is a schematic cross-sectional view of a display device according to an embodiment of the present invention.

### DESCRIPTION OF EMBODIMENTS

A method is known of improving the front luminance of a display device by using the light emitted from the side surface of an LED. However, when the light emitted from the upper surface of the LED is emitted to the outside of the display device, total reflection occurs at the interface between the display device and the air, so that the efficiency of extracting the light emitted from the upper surface of the LED is not always high. That is, the front luminance of the display device (or the efficiency of extracting light in the front direction of the display device) is not always improved.

In view of the above problems, one of the objects of an embodiment of the present invention is to provide a display device with improved front luminance by adjusting a direction of light emitted from an upper surface of a light emitting element.

Hereinafter, embodiments of the present invention are described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

The expressions “a includes A, B or C”, “a includes any of A, B and C”, “a includes one selected from the group consisting of A, B and C”, and “a includes one selected from the group consisting of A, B and C” do not exclude the case where α includes a plurality of combinations of A to C unless otherwise specified. Furthermore, these expressions do not exclude the case where a includes other elements.

In the present specification, although the phrase “above” or “above direction” or “below” or “below direction” is used for convenience of explanation, in principle, the direction from a substrate toward a structure is referred to as “above” or “above direction” with reference to a substrate in which the structure is formed. Conversely, the directions from the structure to the substrate are referred to as “below” or “below direction”. Therefore, in the expression of the light emitting element over the substrate, one surface of the light emitting element facing the substrate is the bottom surface of the light emitting element and the other surface is the top surface of the light emitting element. In addition, the expression “the light emitting element over the substrate” only explains the vertical relationship between the substrate and the light emitting element, and another member may be placed between the substrate and the light emitting element. Furthermore, the terms “above” or “above direction” or “below” or “below direction” mean the order of stacked layers in the structure in which a plurality of layers are stacked, and may not be related to the position in which layers are superimposed in a plan view.

In this specification, “display device” is intended to include a wide range of devices that display a still image or moving image, and may include not only a display panel and a display module but also a device to which other optical members (for example, a polarizing member or touch panel, etc.) are attached.

The following embodiments may be combined with each other as long as there is no technical contradiction.

### First Embodiment

### 1. Configuration of Display Device

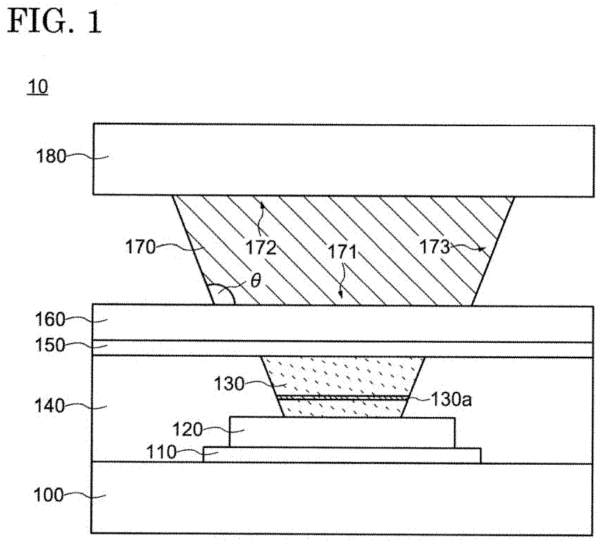

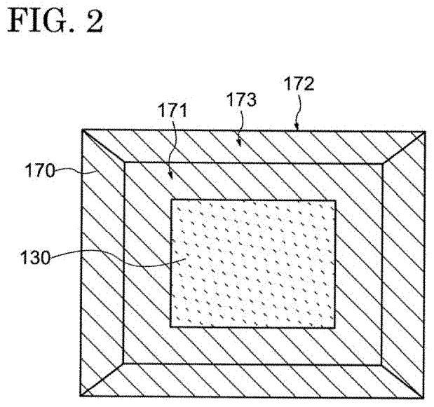

A display device 10 according to an embodiment of the present invention is described with reference to FIGS. 1 and 2.

FIG. 1 is a schematic cross-sectional view of a display device 10 according to an embodiment of the present invention. As shown in FIG. 1, the display device 10 includes a substrate 100, a first conductive layer 110, a second conductive layer 120, a light emitting element 130, a flattening layer 140, a transparent conductive layer 150, a protective layer 160, an optical adjusting member 170, and a protective substrate 180. The light emitting element 130 is electrically connected to the first conductive layer 110 through the second conductive layer 120. Further, the light emitting element 130 is electrically connected to the transparent conductive layer 150.

The substrate 100 is a substrate for mounting the light emitting element 130. For example, a flexible substrate such as a polyimide substrate, an acrylic substrate, a siloxane substrate, or a fluororesin substrate can be used as the substrate 100. Impurities may be introduced into the flexible substrate in order to improve heat resistance of the substrate 100. When the substrate 100 does not need to have flexibility, a rigid substrate such as a glass substrate, a quartz substrate, or a sapphire substrate can be used as the substrate 100. Further, when the substrate 100 does not need to have translucency, a semiconductor substrate such as a silicon substrate, a silicon carbide substrate, a compound semiconductor substrate, or a conductive substrate such as a stainless steel substrate, or the like is used as the substrate 100. Although the details are not shown in figures, the substrate 100 may be a so-called circuit substrate on which a circuit for driving the light emitting element 130 is formed. Further, the structure from the substrate 100 to the protective layer 160, excluding the optical adjustment member 170 and the protective substrate 180 of the display device 10, may be referred to as an array substrate.

The first conductive layer 110 is provided on the substrate 100. The first conductive layer 110 is a wiring layer for supplying current to one of the electrodes of the light emitting element 130. Further, the first conductive layer 110 may be a reflective layer that reflects the light emitted from the light emitting element 130. For example, aluminum or silver can be used for the first conductive layer 110.

The second conductive layer 120 is provided on the first conductive layer 110. The second conductive layer 120 is a connection electrode that connects the light emitting element 130 to the substrate 100 (specifically, connects one of the electrodes of the light emitting element 130 and the first conductive layer 110). For example, silver paste or solder can be used for the second conductive layer 120.

The light emitting element 130 is provided on the second conductive layer 120. The light emitting element 130 includes a light emitting layer 130a that emits light. The light emitting element 130 is, for example, a light emitting diode (LED). The light emitting diode includes a mini LED or a micro LED. For example, a red light emitting diode, a green light emitting diode, a blue light emitting diode, or an ultraviolet light emitting diode, and the like can be used as the light emitting diode.

The flattening layer 140 is provided so as to fill steps of the first conductive layer 110, the second conductive layer 120, and the light emitting element 130. The flattening layer 140 flattens steps such as the light emitting element 130 mounted over the substrate 100. For example, an acrylic resin or a polyimide resin can be used as the material of the flattening layer 140.

The transparent conductive layer 150 is provided on the light emitting element 130 and the flattening layer 140. The transparent conductive layer 150 is a wiring layer for supplying current to the other of the electrodes of the light emitting element 130. Further, the transparent conductive layer 150 can transmit the light emitted from the light emitting element 130. For example, a transparent conductive oxide such as indium tin oxide (ITO) or indium zinc oxide (IZO) can be used for the transparent conductive layer 150. In addition, a thin film metal having translucency can be used for the transparent conductive layer 150. For example, the transparent conductive layer 150 may have a stacked structure such as ITO/Ag/ITO in which a metal such as silver (Ag) is sandwiched between transparent conductive oxides. Although the details are not shown in figures, the transparent conductive layer 150 may be patterned in a predetermined pattern.

The protective layer 160 is provided on the transparent conductive layer 150. The protective layer 160 protects the light emitting element 130 or the transparent conductive layer 150. For example, an inorganic material such as silicon oxide (SiOₓ), silicon nitride oxide (SiOₓN_{y}), silicon nitride (SiNₓ), silicon oxynitride (SiNₓO_{y}), aluminum oxide (AlOₓ), aluminum nitride oxide (AlOₓN_{y}), aluminum oxynitride (AlNₓO_{y}), aluminum nitride (AlNₓ), or the like can be used for the protective layer 160. Here, SiOₓN_{y} and AlOₓN_{y} are silicon compounds and aluminum compounds containing nitrogen (N) in an amount smaller than oxygen (O). On the other hand, SiNₓO_{y} and AlNₓO_{y} are silicon compounds and aluminum compounds containing oxygen in an amount smaller than nitrogen. In addition, not only the above mentioned inorganic insulating material but also an organic insulating material can be used for the protective layer 160. A polyimide resin, an acrylic resin, an epoxy resin, a silicone resin, a fluororesin, a siloxane resin, or the like can be used as the organic insulating material. Further, the protective layer 160 may have a single layer structure of the inorganic insulating layer material or an organic insulating material, or may have a stacked structure of the inorganic insulating layer material and an organic insulating material.

The optical adjusting member 170 is provided on the protective layer 160. The optical adjusting member 170 adjusts the traveling direction of the light emitted from the light emitting element 130. The light emitting element 130 is located in the direction of the lower surface 171 of the optical adjustment member 170. The optical adjustment member 170 adjusts the traveling direction of the light so that the light incident on the lower surface 171 is emitted from the upper surface 172 of the optical adjustment member 170. The details of adjusting the traveling direction of light in the optical adjusting member 170 are described later.

Here, the positional relationship between the light emitting element 130 and the optical adjusting member 170 is described with reference to FIG. 2 in addition to FIG. 1.

FIG. 2 is a schematic plan view illustrating a positional relationship between the light emitting element 130 and the optical adjusting member 170 in the display device 10 according to the embodiment of the present invention. Specifically, FIG. 2 is a plan view of the optical adjusting member 170 as viewed from the lower surface 171 direction. As shown in FIG. 2, in a plan view, the planar shape of the optical adjusting member 170 (the shape of the lower surface 171 and the upper surface 172 of the optical adjusting member 170) is rectangular. However, the planar shape of the optical adjusting member 170 is not limited to this shape. The planar shape of the optical adjusting member 170 may be polygonal. Further, although the center position of the lower surface 171 of the optical adjustment member 170 may substantially coincide with the center position of the upper surface of the light emitting element 130 in a plan view, the configuration is not limited to this structure.

In a plan view, the area of the upper surface 172 of the optical adjusting member 170 is larger than the area of the lower surface 171 of the optical adjusting member 170. Therefore, the side surface of the optical adjustment member 170 has a taper and is connected with the lower surface 171 and the upper surface 172. The shape of the optical adjusting member 170 is a so-called quadrangular frustum. The tapered angle θ of the side surface 173 with respect to the lower surface 171 is, for example, greater than or equal to 95° and less than or equal to 150°, preferably greater than or equal to 100° and less than or equal to 130°. The height of the optical adjusting member 170, that is, the distance from the lower surface 171 to the upper surface 172 is, for example, greater than or equal to 3 μm and less than or equal to 60 μm, preferably greater than or equal to 10 μm and less than or equal to 40 μm. For example, an acrylic resin or an epoxy resin can be used for the optical adjusting member 170. Further, the optical adjusting member 170 may be an adhesive material such as an acrylic resin or an epoxy resin.

In a plan view, the optical adjusting member 170 is provided so as to overlap the entire light emitting element 130. That is, the lower surface 171 of the optical adjustment member 170 overlaps the entire upper surface of the light emitting element 130. Therefore, the length of one side of the lower surface 171 of the optical adjustment member 170 is larger than the width of the upper surface of the light emitting element 130.

The protective substrate 180 is provided on the optical adjusting member 170. The protective substrate 180 protects the optical adjustment member 170 and the array substrate. The protective substrate 180 may be a support substrate for the optical adjustment member 170. The protective substrate 180 can transmit the light emitted from the light emitting element 130. For example, a translucent substrate such as a polyimide substrate, an acrylic substrate, a siloxane substrate, a fluororesin substrate, or a glass substrate can be used as the protective substrate 180.

### 2. Modification of the Optical Adjustment Member 170

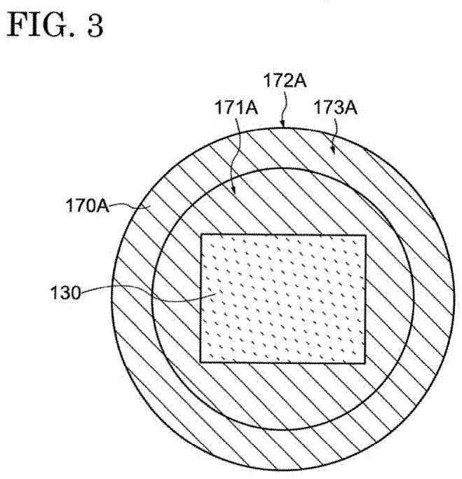

An optical adjustment member 170A, which is a modification of the optical adjustment member 170 of the display device 10, is described with reference to FIG. 3. When the configuration of the optical adjusting member 170A is the same as the configuration of the optical adjusting member 170, the description of the configuration of the optical adjusting member 170A may be omitted.

FIG. 3 is a schematic plan view illustrating the positional relationship between the light emitting element 130 and the optical adjusting member 170A in the display device 10 according to an embodiment of the present invention. Specifically, FIG. 3 is a plan view of the optical adjusting member 170A as viewed from a lower surface 171A direction. As shown in FIG. 3, in a plan view, the planar shape of the optical adjusting member 170A (the shape of the lower surface 171A and an upper surface 172A of the optical adjusting member 170A) is circular. However, the planar shape of the optical adjusting member 170A is not limited to this shape. The planar shape of the optical adjusting member 170A may be elliptical. Further, although the center position of the lower surface 171A of the optical adjustment member 170A may be substantially the same as the center position of the upper surface of the light emitting element 130 in a plan view, the configuration is not limited to this structure.

In a plan view, the area of the upper surface 172A of the optical adjusting member 170A is larger than the area of the lower surface 171A of the optical adjusting member 170A. Therefore, the side surface 173A of the optical adjustment member 170A also has a taper and is connected to the lower surface 171A and the upper surface, similar to the side surface 173 of the optical adjustment member 170. The shape of the optical adjusting member 170A is a so-called truncated cone.

In a plan view, the optical adjustment member 170A is also provided so as to overlap the entire light emitting element 130. That is, the lower surface 171A of the optical adjustment member 170A overlaps the entire upper surface of the light emitting element 130. Therefore, the diameter of the lower surface 171A of the optical adjusting member 170A is larger than the length of the diagonal line of the light emitting element 130.

Although the optical adjustment member 170A is described as a modification of the optical adjustment member 170, a modification of the optical adjustment member 170 is not limited to thereto. For example, the optical adjusting member may have a structure in which the lower surface is rectangular and the upper surface is circular. Alternatively, the optical adjusting member may have a structure in which the lower surface is circular and the upper surface is rectangular.

### 3. Method of Manufacturing Display Device 10

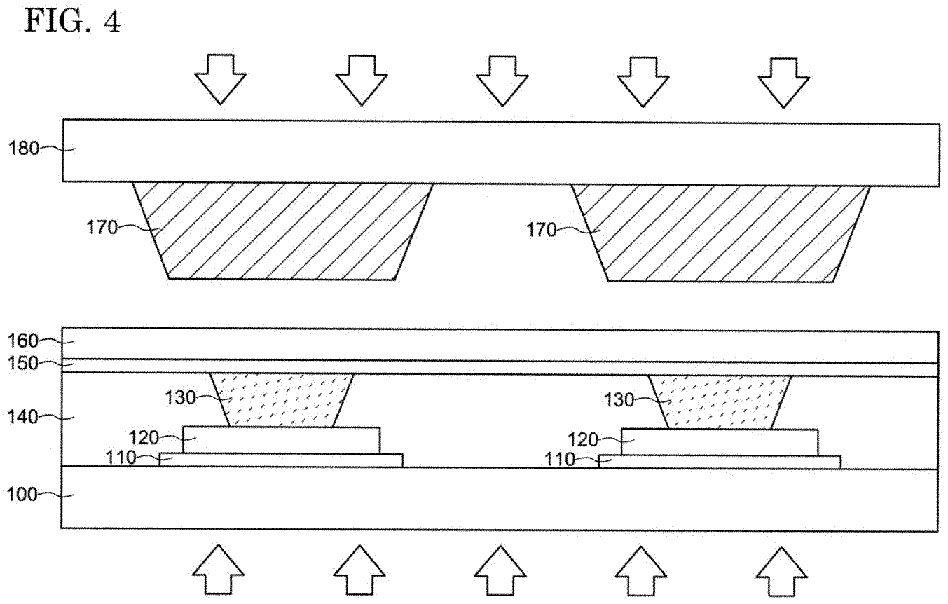

A method of manufacturing the display device 10 is described with reference to FIG. 4.

FIG. 4 is a schematic cross-sectional view illustrating a method of manufacturing the display device 10 according to the embodiment of the present invention. The display device 10 is manufactured by laminating the array substrate and a protective substrate 180.

The first conductive layer 110 and the second conductive layer 120 are formed over the substrate 100 which is a base substrate of the array substrate. The first conductive layer 110 is patterned in a predetermined pattern using photolithography. The second conductive layer 120 is formed by applying a silver paste or the like on the first conductive layer 110. The light emitting element 130 is mounted over the substrate 100 so as to be electrically connected to the second conductive layer 120. The flattening layer 140 is formed so as to flatten the steps of the first conductive layer 110, the second conductive layer, and the light emitting element 130. The transparent conductive layer 150 and the protective layer 160 are formed on the light emitting element 130 and the flattening layer 140. The transparent conductive layer 150 is patterned in a predetermined pattern using photolithography.

On the other hand, the optical adjusting member 170 is formed on the protective substrate 180. The optical adjustment member 170 can be patterned in a predetermined pattern using photolithography.

The array substrate and the protective substrate 180 can be attached to each other using an adhesive or a sealing agent. For example, after applying the adhesive to the optical adjusting member 170, the array substrate and the protective substrate 180 can be attached together. Further, after applying the sealant to the peripheral portion of the array substrate or the protective substrate 180, the array substrate and the protective substrate 180 can be attached together. When the optical adjusting member 170 is an adhesive material, the array substrate and the protective substrate 180 may be attached together without using an adhesive. In this case, since the optical adjusting member 170 is in direct contact with the protective layer 160 formed over the substrate 100, it is possible to prevent air bubbles (air) from entering between the protective layer 160 and the optical adjusting member 170. That is, since the reflection at the interface between the protective layer 160 and the optical adjusting member 170 can be suppressed, the effect of improving the front luminance of the display device 10 is enhanced.

In either case, the optical adjusting member 170 serves as a spacer and can hold a gap between the array substrate and the protective substrate 180. The optical adjusting member 170 may be bonded by performing temporary heating and main heating. Here, the temporary heating refers to heating that forms the optical adjusting member 170 in a semi-cured state in which cross-linking has not fully progressed. By performing the main heating following the temporary heating, the cross-linking of the optical adjusting member 170 proceeds, and the optical adjusting member 170 is adhered to the protective layer 160.

### 3. Adjustment of the Traveling Direction of Light by the Optical Adjustment Member 170

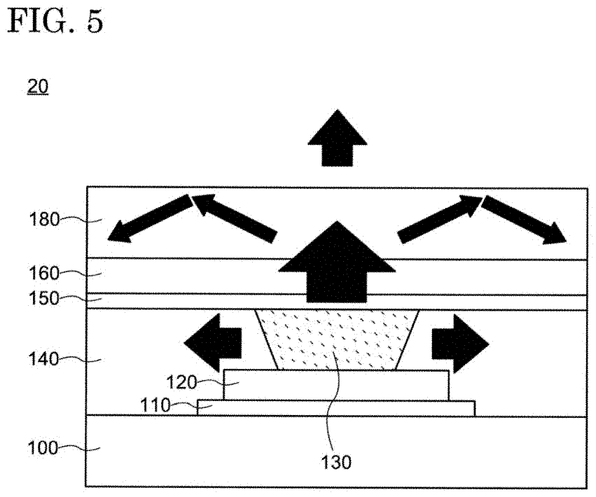

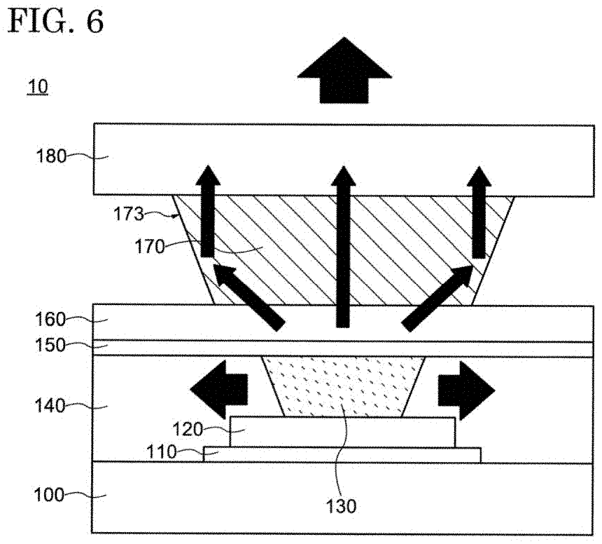

The adjustment of the traveling direction of the light of the optical adjusting member 170 and the front luminance of the display device 10 is described with reference to FIGS. 5 and 6.

FIG. 5 is a schematic cross-sectional view illustrating the traveling direction of light of a display device 20 without the optical adjusting member 170. In the display device 20, the protective substrate 180 is provided on the protective layer 160 without providing the optical adjusting member 170.

As shown in FIG. 5, in the display device 20, the light emitted from the light emitting element 130 is emitted not only from the upper surface of the light emitting element 130 but also from the side surface of the light emitting element 130. The proportions of the light emitted from the upper surface of the light emitting element 130 and the light emitted from the side surface of the light emitting element 130 are about 63% and about 32%, respectively. The remaining light is lost, for example, by being absorbed by the second conductive layer 120 during reflection by the second conductive layer 120. The light emitted from the upper surface of the light emitting element 130 passes through the protective layer 160 and the protective substrate 180 and is emitted to the outside. However, the refractive index of air is smaller than the refractive index of the protective substrate 180. Therefore, the light emitted from the upper surface of the light emitting element 130 is reflected at the interface between the protective substrate 180 and the air due to the difference between the refractive index of the protective substrate 180 and the refractive index of the air. In particular, since light having a large incident angle at the interface between the protective substrate 180 and air (light exceeding the critical angle at the interface between the protective substrate 180 and air) undergoes total reflection, the proportion of the light emitted to the outside of the display device 20 is further reduced. Since total reflection occurs in about 50% of the light emitted from the light emitting element 130, as a result, the proportion of the light emitted to the outside of the display device 20 is reduced to about 31% of the light emitted from the upper surface of the light emitting element 130.

FIG. 6 is a schematic cross-sectional view illustrating the traveling direction of light of the display device 10 according to the embodiment of the present invention. As shown in FIG. 6, in the display device 10, the light emitted from the light emitting element 130 is emitted not only from the upper surface of the light emitting element 130 but also from the side surface of the light emitting element 130. The proportions of the light emitted from the side surface of the light emitting element 130 and the light emitted from the upper surface of the light emitting element 130 does not change between the display device 10 and the display device 20. However, in the display device 10, the light emitted from the upper surface of the light emitting element 130 is incident on the optical adjusting member 170. The outside of the optical adjustment member 170 is air. In other words, the side surface 173 of the optical adjusting member 170 is exposed to air. The refractive index of the optical adjusting member 170 is larger than the refractive index of air. Therefore, the light incident on the optical adjusting member 170 is reflected at the interface between the side surface 173 of the optical adjusting member 170 and the air so as to be directed toward the normal direction of the protective substrate 180. As a result, the light transmitted through the protective substrate 180 has a small critical angle, and total reflection at the interface between the protective substrate 180 and air is suppressed. That is, the proportion of light, which is emitted from the upper surface of the light emitting element 130, emitted from the protective substrate 180 increases. Therefore, the display device 10 has a higher front luminance than the display device 20.

### 4. Example

The display device 10 and the display device 20 were manufactured, and the front luminance of the light emitted from the protective substrate 180 was compared. The front luminance of the display device 10 was 1.5 times the front luminance of the display device 20. In the display device 10, the light emitted from the upper surface of the light emitting element 130 was adjusted by the optical adjusting member 170 so as to be directed toward the normal direction of the protective substrate 180, so that total reflection at the interface between the protective substrate 180 and air was suppressed, and the front luminance of the display device 10 was improved.

As described above, in the display device 10, the traveling direction of the light emitted from the upper surface of the light emitting element 130 can be adjusted by the optical adjusting member 170, and the proportion of the light emitted from the protective substrate 180 can be increased. Therefore, in the display device 10, the front luminance is improved.

### Second Embodiment

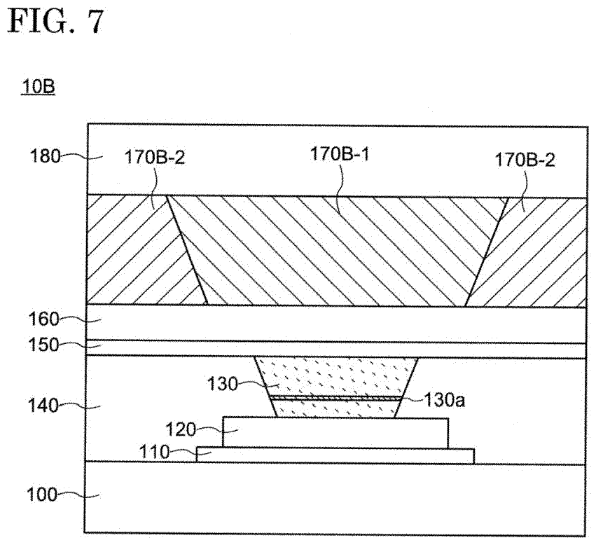

A display device 10B according to an embodiment of the present invention is described with reference to FIG. 7. When the configuration of the display device 10B is the same as the configuration of the display device 10, the description of the configuration of the display device 10B may be omitted.

FIG. 7 is a schematic cross-sectional view of the display device 10B according to an embodiment of the present invention. As shown in FIG. 7, the display device 10B includes a substrate 100, a first conductive layer 110, a second conductive layer 120, a light emitting element 130, a flattening layer 140, a transparent conductive layer 150, a protective layer 160, a first optical adjusting member 170B-1, a second optical adjusting member 170B-2, and a protective substrate 180.

Since the first optical adjusting member 170B-1 has the same configuration as the above-mentioned optical adjusting member 170, the description of the configuration of the first optical adjusting member 170B-1 is omitted here.

The second optical adjusting member 170B-2 is provided so as to surround the periphery of the first optical adjusting member 170B-1. The second optical adjusting member 170B-2 is a material having a refractive index smaller than that of the first optical adjusting member 170B-1. For example, a material obtained by adding fluorine to the material included in the first optical adjusting member 170B-1 can be used as the second optical adjusting member 170B-2. By adding fluorine to a material, the refractive index of the material can be reduced.

In the display device 10B, the light incident on the first optical adjusting member 170B-1 is reflected at the interface between the first optical adjusting member 170B-1 and the second optical adjusting member 170B-2 so as to be directed toward the normal direction of the protective substrate 180. Therefore, the proportion of the light totally reflected at the interface between the protective substrate 180 and the air decreases, and the proportion of the light transmitted through the protective substrate 180 and emitted to the outside increases. Further, since not only the first optical adjusting member 170B-1 but also the second optical adjusting member 170B-2 functions as a spacer or an adhesive, the display device 10B has high impact resistance.

As described above, in the display device 10B, the traveling direction of the light emitted from the upper surface of the light emitting element 130 is adjusted by the first optical adjusting member 170B-1 and the second optical adjusting member 170B-2, and the proportion of the light emitted from the substrate 180 can be increased. Therefore, in the display device 10B, the front luminance is improved.

### Third Embodiment

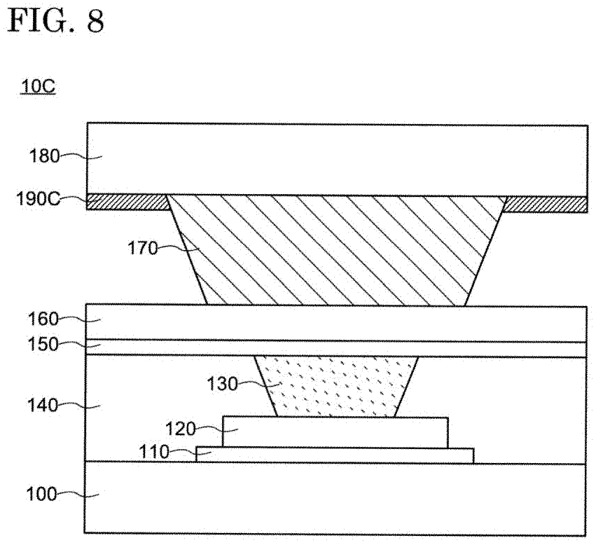

A display device 100 according to an embodiment of the present invention is described with reference to FIG. 8. When the configuration of the display device 100 is the same as the configuration of the display device 10, the description of the configuration of the display device 10C may be omitted.

FIG. 8 is a schematic cross-sectional view of the display device 100 according to an embodiment of the present invention. As shown in FIG. 6, the display device 100 includes a substrate 100, a first conductive layer 110, a second conductive layer 120, a light emitting element 130, a flattening layer 140, a transparent conductive layer 150, a protective layer 160, an optical adjusting member 170, a black matrix 190C, and a protective substrate 180.

The black matrix 190C is provided around the optical adjusting member 170 on the protective substrate 180. The black matrix 190C prevents color mixing of the light emitted by the adjacent light emitting elements 130. Further, the black matrix 190C absorbs the external light transmitted through the protective substrate 180 and suppresses the reflection of the external light. Therefore, in the display device 10C, the contrast of the display is improved.

The black matrix 190C is formed on the protective substrate 180. The black matrix 190C is patterned using photolithography so that a predetermined area is opened. The optical adjusting member 170 is provided in the opening of the black matrix 190C.

As described above, in the display device 100, the traveling direction of the light emitted from the upper surface of the light emitting element 130 can be adjusted by the optical adjusting member 170, and the proportion of the light emitted from the protective substrate 180 can be increased. Further, in the display device 100, the contrast of the display is improved by the black matrix 190C. Therefore, in the display device 100, not only the front luminance but also the visibility are improved.

### Fourth Embodiment

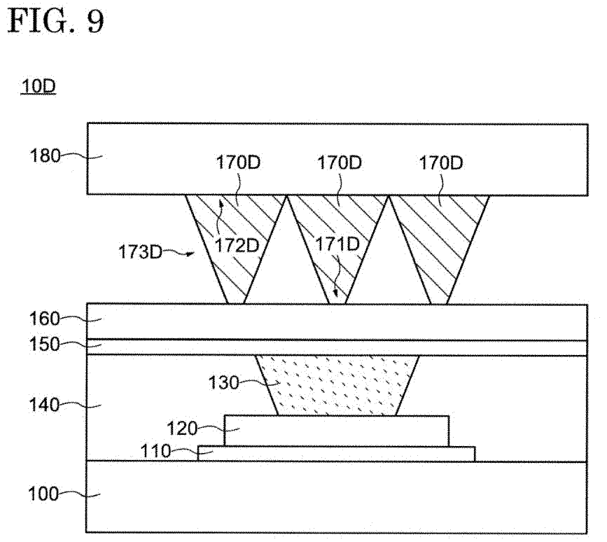

A display device 10D according to an embodiment of the present invention is described with reference to FIG. 9. When the configuration of the display device 10D is the same as the configuration of the display device 10, the description of the configuration of the display device 10D may be omitted.

FIG. 9 is a schematic cross-sectional view of the display device 10D according to an embodiment of the present invention. The display device 10D includes a substrate 100, a first conductive layer 110, a second conductive layer 120, a light emitting element 130, a flattening layer 140, a transparent conductive layer 150, a protective layer 160, a plurality of optical adjusting members 170D, and a protective substrate 180.

Since each of the plurality of optical adjusting members 170D has the same configuration as the above-mentioned optical adjusting member 170, the details are omitted. The plurality of optical adjusting members 170D may have the same or different shapes. The total area of the upper surface of the plurality of optical adjusting members 170D is larger than the total area of the lower surface of the plurality of optical adjusting members 170D. Further, the tapered angles of side surfaces 173D with respect to lower surfaces 171D of the plurality of optical adjusting members 170D may be the same or different. Furthermore, the number of the plurality of optical adjusting members 170D is not particularly limited.

Although upper surfaces 172D of the plurality of optical adjusting members 170D preferably forms one plane without gaps, the configuration of the plurality of optical adjusting members is not limited this structure. The upper surfaces 172D of the plurality of optical adjusting members 170D may be separated from each other. The gaps between the plurality of optical adjusting members 170C may be filled with a material having a refractive index lower than that of the optical adjusting member 170D.

Although it is not always necessary that all of the plurality of optical adjusting members 170D overlap the light emitting element 130, in a plan view, it is preferable that at least a part of the plurality of optical adjusting members 170D are arranged so that the plurality of optical adjusting members 170D overlap the light emitting element 130. That is, it is preferable that the plurality of optical adjustment members 170D are arranged wider than the range in which they overlap the light emitting element 130. By arranging the plurality of optical adjusting members 170D in such an arrangement, the same effect as that of the display device 10 described above can be obtained.

As described above, in the display device 10D, the traveling direction of the light emitted from the upper surface of the light emitting element 130 is adjusted by the plurality of optical adjusting members 170D, and the proportion of the light emitted from the protective substrate 180 is increased. Further, it is possible to collect light in the normal direction of the protective substrate 180 while reflecting the light in an arbitrary direction by the plurality of optical adjusting members 170D. Therefore, in the display device 10D, uniformed light can be extracted and the front luminance is improved.

Each of the embodiments described above as an embodiment of the present invention can be appropriately combined and implemented as long as they do not contradict each other. Additions, deletion, or design changes of constituent elements, or additions, omissions, or changes to conditions of steps as appropriate based on a display device of the respective embodiments are also included within the scope of the present invention as long as the gist of the present invention is provided.

Other effects of the action which differ from those brought about by each of the above described embodiments, but which are apparent from the description herein or which can be readily predicted by those skilled in the art, are naturally understood to be brought about by the present invention.

What is claimed is:

1. A display device comprising:
a light emitting element; and
a first optical adjustment member located over the light emitting element and overlapping the light emitting element,
wherein an area of an upper surface of the first optical adjustment member is larger than an area of a lower surface of the first optical adjustment member.

2. The display device according to claim 1, wherein a distance from the lower surface to the upper surface is greater than or equal to 3 μm and less than or equal to 60 μm.

3. The display device according to claim 1, wherein an inclination angle of a side surface of the first optical adjustment member with respect to the lower surface is greater than or equal to 95° and less than or equal to 150°.

4. The display device according to claim 1, wherein a side surface of the first optical adjustment member is exposed to air.

5. The display device according to claim 1, further comprising a second optical adjustment member in contact with a side surface of the first optical adjustment member,
wherein a refractive index of the second optical member is smaller than a refractive index of the first optical adjustment member.

6. The display device according to claim 1, wherein in a plan view, a plane shape of the first optical adjustment member is a polygon, a circle, or an ellipse.

7. The display device according to claim 1, further comprising a protective substrate over the first optical adjustment member,
wherein the protective substrate comprises a black matrix provided around the first optical adjustment member.

8. The display device according to claim 1, wherein in a plan view, the first optical adjustment member overlaps the entire light emitting element.

9. The display device according to claim 1, wherein the first optical adjustment member is an adhesive material.

10. The display device according to claim 9, wherein the adhesive material comprises an acrylic resin or an epoxy resin.

11. A display device comprising:
a light emitting element; and
a plurality of first optical adjustment members located over the light emitting element and overlapping the light emitting element,
wherein an total area of an upper surface of the plurality of first optical adjustment members is larger than an total area of a lower surface of the plurality of first optical adjustment members.

12. The display device according to claim 11, wherein a distance from the lower surface to the upper surface is greater than or equal to 3 μm and less than or equal to 60 μm.

13. The display device according to claim 11, wherein an inclination angle of a side surface of each of the plurality of first optical adjustment members with respect to the lower surface is greater than or equal to 95° and less than or equal to 150°.

14. The display device according to claim 11, wherein a side surface of each of the plurality of first optical adjustment members is exposed to air.

15. The display device according to claim 11, further comprising a second optical adjustment member in contact with a side surface of each of the plurality of first optical adjustment members,
wherein a refractive index of the second optical member is smaller than a refractive index of each of the plurality of first optical adjustment members.

16. The display device according to claim 11, wherein in a plan view, a plane shape of each of the plurality of first optical adjustment members is polygonal, circular, or an elliptical.

17. The display device according to claim 11, further comprising a protective substrate over the plurality of first optical adjustment members,
wherein the protective substrate comprises a black matrix, provided around the plurality of first optical adjustment members.

18. The display device according to claim 11, wherein in a plan view, the plurality of first optical adjustment members overlaps the entire light emitting element.

19. The display device according to claim 11, wherein each of the plurality of first optical adjustment members is an adhesive material.

20. The display device according to claim 19, wherein the adhesive material comprises an acrylic resin or an epoxy resin.
